(19) United States
(12) Patent Application Publication
(10) Pub. No.: US 2010/0096254 A1
(43) Pub. Date: Apr. 22, 2010

(54) DEPOSITION SYSTEMS AND METHODS

(76) Inventor: Hari Hegde, San Jose, CA (US)

Correspondence Address: IPSG, P.C., P.O. BOX 700640, SAN JOSE, CA, 95170, US

(21) Appl. No.: 12/571,160

(22) Filed: Sep. 30, 2009

Related U.S. Application Data
(63) Continuation-in-part of application No. 12/256,416, filed on Oct. 22, 2008.

(51) Int. Cl. C23C 14/35

(52) U.S. Cl. 204/192.12; 204/298.16; 204/298.17; 204/298.2

(57) ABSTRACT

A system for depositing material on a substrate using plasma and a target. The target may include the material and/or a second material. The system may include a plasma source for providing the plasma. The system may also include a chamber for containing the substrate, the plasma, and the target during deposition of the material on the substrate. The system may also include a first magnet disposed above the chamber or disposed below the chamber for influencing distribution of the plasma inside the chamber. At least one of a bottom surface of the magnet and a top surface of the magnet is at an angle with respect to an imaginary axis of the plasma source. A circular cross section of the plasma source is symmetrical with respect to the imaginary axis of the plasma source. The angle is greater than 0 degree and less than 90 degrees.

### CROSS-REFERENCE TO RELATED APPLICATIONS/PRIORITY CLAIM

This application is a continuation-in-part application under 37 CFR 1.53(b) of and claims the benefit under 35 U.S.C. 120 of a commonly assigned utility patent application entitled “PLASMA ENHANCED SPUTTERING SYSTEMS AND METHODS THEREFOR,” by Hari Hegde, Attorney Docket Number AVPT-P004, application Ser. No. 12/256,416 filed on Oct. 22, 2008, which is incorporated herein by reference.

### BACKGROUND OF THE INVENTION

Plasma sputtering has been employed for facilitating deposition of materials on surfaces of substrates. The substrates, once processed, may be employed to manufacture devices such as semiconductor devices, disk drive read/write heads, micro or nanomachines, etc.

In a typical plasma sputtering system, plasma is generated from a source gas. Ions in the plasma are directed toward a target, which may include material to be deposited onto a substrate. The impinging ions strike or sputter off material from the target. The sputtered material may land on the substrate and therefore to be deposited on the substrate.

Generally speaking, as ions accelerate toward the target, sputtered material tends to be sputtered off in the direction that is substantially perpendicular to the target surface from which the sputtered material is ejected. For example, if the target is cylindrical, as a typical target configuration, the sputtered material tends to be broadcasted isotropically in various directions. As a result, only a relatively small portion of the sputtered material may end up being deposited on the substrate, but most of the sputtered material may be deposited on the interior surfaces of the plasma chamber. Frequent cleaning of the chamber may be required, substantially incurring maintenance costs and reducing productivity of the sputtering system. This unwanted sputtering represents inefficient utilization of the target material and may undesirably contribute to material costs in manufacturing devices.

Additionally, some of the sputtered material may be back-sputtered toward the plasma source. The back-sputtering material may significantly reduce the useful life of the plasma source and/or may require frequent cleaning of plasma source. As a result, additional costs may be incurred, and productivity may be further reduced.

### SUMMARY OF INVENTION

An embodiment of the present invention relates to a system for depositing material on a substrate using plasma and a target. The target may include the material and/or a second material. The system may include a plasma source for providing the plasma. The system may also include a chamber for containing the substrate, the plasma, and the target during deposition of the material on the substrate. The system may also include a first magnet disposed above the chamber or disposed below the chamber for influencing distribution of the plasma inside the chamber. At least one of a bottom surface of the magnet and a top surface of the magnet is at an angle with respect to an imaginary axis of the plasma source. A circular cross section of the plasma source is symmetrical with respect to the imaginary axis of the plasma source. The angle is greater than 0 degree and less than 90 degrees.

The above summary relates to only one of the many embodiments of the invention disclosed herein and is not intended to limit the scope of the invention, which is set forth is the claims herein. These and other features of the present invention will be described in more detail below in the detailed description of the invention and in conjunction with the following figures.

### BRIEF DESCRIPTION OF THE DRAWINGS

The present invention is illustrated by way of example, and not by way of limitation, in the figures of the accompanying drawings and in which like reference numerals refer to similar elements and in which:

FIG. 1 shows a schematic representation illustrating a deposition system in accordance with one or more embodiments of the invention.

FIG. 2 shows a schematic representation illustrating a deposition system in accordance with one or more embodiments of the invention.

FIG. 3 shows a schematic representation illustrating a deposition system in accordance with one or more embodiments of the invention.

### DETAILED DESCRIPTION OF EMBODIMENTS

The present invention will now be described in detail with reference to a few embodiments thereof as illustrated in the accompanying drawings. In the following description, numerous specific details are set forth in order to provide a thorough understanding of the present invention. It will be apparent, however, to one skilled in the art, that the present invention may be practiced without some or all of these specific details. In other instances, well known process steps and/or structures have not been described in detail in order to avoid unnecessarily obscuring the present invention.

Various embodiments are described herein below, including methods and techniques. It should be kept in mind that the invention might also cover articles of manufacture that includes a computer readable medium on which computer-readable instructions for carrying out embodiments of the inventive technique are stored. The computer readable medium may include, for example, semiconductor, magnetic, opto-magnetic, optical, or other forms of computer readable medium for storing computer readable code. Further, the invention may also cover apparatuses for practicing embodiments of the invention. Such apparatus may include circuits, dedicated and/or programmable, to carry out tasks pertaining to embodiments of the invention. Examples of such apparatus include a general-purpose computer and/or a dedicated computing device when appropriately programmed and may include a combination of a computer/computing device and dedicated/programmable circuits adapted for the various tasks pertaining to embodiments of the invention.

Embodiments of the invention relate to a deposition system for processing a substrate (such as a substrate for use in the manufacture of integrated circuits or hard disk read/write heads). The deposition system, in one or more embodiments, may include a support mechanism for tilting a sputter target (or “target”) such that the target may have a sputtering surface tilted at an angle (e.g., an acute angle) other than orthogonal relative to the imaginary central axis of the plasma source, wherein a circular cross section of a cylindrical portion of the plasma source is symmetrical with respect the to imaginary central axis. By tilting the target sputtering surface mostly toward the substrate and away from the plasma source, the deposition system may minimize the amount of sputtered material(s) back-sputtered onto the plasma source. Advantageously, the service life of the plasma source may be prolonged.

The deposition system may also include at least a shield to further reduce unwanted sputtering on the plasma source and/or the plasma chamber interior. The shield may be grounded or electrically floating for shielding one or more surfaces of the sputter target. The shielded surface or surfaces may represent sputter target regions from which material sputtering is undesired. For example, if the sputter target is a polygonal or circular disk, one surface of the disk may be tilted toward the substrate and exposed for sputtering by the plasma. This surface is referred to herein as the “target sputtering surface.” The other surfaces of the disk may be shielded to minimize sputtering. By minimizing unwanted sputtering of other surfaces of the sputter target, the useful life of the sputter target may be extended. Further, sputter material buildup in the plasma source interior, along chamber walls, and in other components of the chamber may be reduced. As a result, the deposition system may be operated for a longer period of time between maintenance cycles. Advantageously, maintenance costs for the deposition system may be reduced, and productivity of the deposition system may be improved.

In one or more embodiments, the deposition system may include a substrate holder to position the substrate such that the substrate is also angled substantially toward the target sputtering surface. Preferably, the substrate is positioned away from the imaginary central axis of the plasma source such that sputtered material(s) directed toward the substrate are at an angle that is away from the plasma source. By directing the sputtered material(s) away from the plasma source, unwanted back-sputtered material(s) deposited onto the plasma source may be substantially reduced.

By tilting the target mostly toward the substrate and away from the plasma source and/or tilting the substrate toward the target, the deposition system may also improve target utilization. The deposition system may also provide improved step coverage of 3-dimensional features on substrates, compared with conventional deposition systems with targets arranged orthogonal to plasma sources.

In one or more embodiments, the deposition system may include a plurality of magnets (i.e., at least two magnets) to produce at least a magnetic field. The deposition system may include arrangements and/or mechanisms to steer and/or shape magnetic field lines with respect to the target. In one or more embodiments, these magnets may be asymmetrical, for example, provided with different current amperages to produce magnetic fields of different strengths. Alternatively or additionally, the position and/or physical size of one or more of the magnets (e.g., coil magnets) may be different from the other(s). For example, the diameters of the coil magnets may be different, or the windings may be different, or the positions of one or more of the magnets may be moved along the direction of the imaginary central axis of the plasma source or perpendicular thereto to achieve field shaping. In one or more embodiments, the magnets may be arranged and/or configured symmetrically with respect to each other or with respect to one another.

When the target is positioned between the plurality of magnets, the magnetic field lines may be shaped (via, for example, different currents, different sizes, different windings, different positions, etc. of the magnets) to pass through the target with desired field line strength(s) and/or in one or more desirable directions. In one or more embodiments, the deposition system may include mechanisms (e.g., for changing the positions of the magnets or the currents provided to the magnets) that enable adjusting magnetic field strengths when the sputtering/deposition is being performed, or in situ.

In one or more embodiments, the deposition system may include a multi-target holder for supporting a plurality of targets and for indexing the targets into suitable positions. The multi-target holder may enable different materials to be sputtered onto the substrate at different steps of the process recipe. When one target is sputtered by the plasma, the other targets may be positioned outside of the plasma cloud and/or may be shielded to minimize or eliminated unintended sputtering of the other targets.

One or more embodiments of the invention relate to a deposition system for depositing material on a substrate. The system may provide plasma to physically and/or chemically interact with a target for sputtering/depositing the material onto the substrate. The target may include the sputtered material and/or at least a different type of material employed for producing the sputtered material in the deposition process. The system may include a plasma source for providing the plasma. The system may also include a chamber for containing the substrate, the plasma, and the target during the deposition process. Prior to the deposition process and/or during the deposition process, the target may be tilted for minimizing unwanted deposition on the plasma source and/or for improving the uniformity of material deposition on the substrate. The substrate may be properly oriented according to the orientation of the target for optimizing deposition efficiency and/or deposition uniformity.

The system may also include one or more magnets, for example, disposed outside of the chamber, for steering the plasma to the target and/or for focusing the plasma on the target. According to the tilted orientation of the target, the magnet(s) may be configured with one or more tilted orientations to compensate for effects of the potentially lower plasma density at the lower portion of the target (which is relatively farther from the plasma source than the upper portion of the target). Advantageously, the uniformity of target utilization and consumption may be improved.

In one or more embodiments, the deposition system may include a top magnet disposed above the chamber and/or a bottom magnet disposed below the chamber. The top magnet and/or the bottom magnet may be oriented to be at an acute angle between 0 degree and 90 degrees, e.g., at least 75 degrees and less than 90 degrees, with respect to an imaginary axis of the plasma source, wherein a circular cross section of the plasma source may be symmetrical with respect to the imaginary axis of the plasma source. With the tilted orientation(s), the top magnet and/or the bottom magnet may produce at least a magnetic field with relatively more magnetic field lines passing through the lower portion of the tilted target, thereby increasing the plasma density at the lower part of the sputtering surface of the target to compensate for the potential plasma density differences across the sputtering surface of the target caused by the tilted orientation of the target. As a result, plasma density may be substantially uniform over the sputtering surface of the target, and the consumption of the target may be substantially uniform across the sputtering surface of the target. Advantageously, target material may be optimally utilized, waste of target material potentially caused by uneven or concentrated consumption of targets may be minimized, costs associated with target material may be minimized, costs and time required for replacing targets may be minimized, and productivity for manufacturing devices may be improved.

One or more embodiments of the invention relate to a method for manufacturing the deposition system. The method may include configuring the top magnet and/or the bottom magnet to be at an acute angle between 0 degree and 90 degrees, e.g., at least 75 degrees and less than 90 degrees, with respect to the imaginary axis of the plasma source. As discussed above, the deposition system may advantageously enable reducing material cost and improving productivity.

One or more embodiments of the invention relate to a method for depositing material on a substrate using plasma and a target. The method may include disposing the substrate and the target inside a chamber, wherein chamber is also configured for containing the plasma. The target may be disposed with the sputtering surface (i.e., the surface of the target intended to be interacting with the plasma) facing the substrate. The method may also include orienting (or tilting) the target such that the target is at an acute angle with respect to the imaginary axis of the plasma source, for minimizing unwanted deposition on the plasma source and/or for depositing the material on the substrate in an efficient and uniform manner, with effects of the gravity taken into consideration. The method may also include orient the substrate according to the orientation of the target for optimizing deposition efficiency and/or deposition uniformity.

The method may also include producing at least a magnetic field inside the chamber using a top magnet (disposed above the chamber) and/or a bottom magnet (disposed below the chamber) for influencing the distribution of the plasma inside the chamber. The method may also include arranging the target, the top magnet, and/or the bottom magnet to make an imaginary center line of the magnetic field pass through the sputtering surface of the target at a point lower than a center of the sputtering surface. In other words, the method may include directing more magnetic field lines to pass through the lower portion of the tilted target than the upper portion of the tilted target, which is closer to the plasma source than the lower portion of the target given the tilted orientation of the target. Accordingly, the method may compensate for the potential plasma density differences across the sputtering surface of the target caused by the tilted orientation of the target. Advantageously, the utilization of the target may be optimized, costs and time required for replacing targets may be minimized, and productivity for manufacturing devices may be improved.

In one or more embodiments, the method may include adjusting the orientation(s) of the target, the top magnet, and/or the bottom magnet during the deposition process. Advantageously, the utilization of the target may be dynamically optimized.

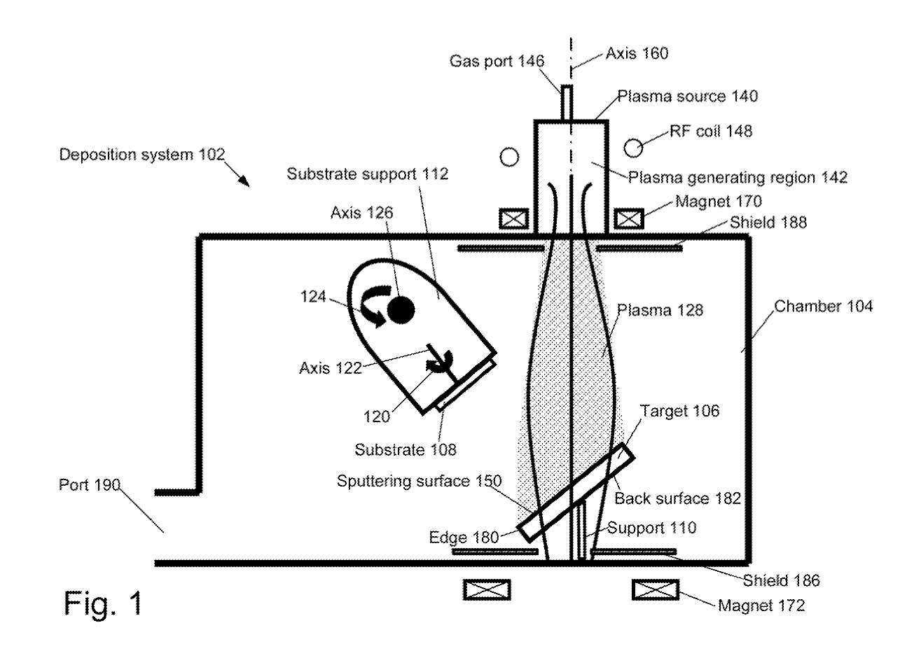

The features and advantages of the invention may be better understood with reference to the figures and discussions that follow. FIG. 1 shows a schematic representation illustrating a deposition system 102 in accordance with one or more embodiments of the invention. Deposition system 102 may include a chamber 104, inside which a target 106 and a substrate 108 may be disposed. Target 106 is mechanically supported by target support 110. Substrate 108 is held in position by substrate support 112. In one or more embodiments, substrate support 112 is capable of rotating substrate 108 in situ around axis 122 (in the direction of arrow 120) and/or tilting around axis 126 in the direction of arrow 124. However, such in-situ rotating and/or tilting of substrate 108 may be optional and may not be required in some embodiments of the present invention. The rotating and/or the tilting of substrate 108 may also be performed prior to the deposition process and/or between process steps. Preferably, substrate 108 is positioned away from the plasma path 128 but directed toward a target sputtering surface 150 of target 106 to maximize the deposition of sputtered material on substrate 108.

Likewise, target support 110 may be capable, in one or more embodiments, of rotating and/or tilting target 106. However, such in situ rotating and/or tilting of target 106 may be optional and may not be required in some embodiments of the present invention. The orientation and/or the position of target 106 may be fixed during the deposition process, in one or more embodiments, or may be adjustable in-situ, in one or more other embodiments. The rotating and/or the tilting of target 106 may also be performed prior to the deposition process and/or between process steps.

FIG. 1 also shows a plasma source 140 having plasma generating region 142. Inside plasma generating region 142, plasma is generated from source gas, which is injected into plasma generating region 142 via one or more gas ports 146. The source gas is ignited into a set of plasma and sustained in plasma generating region 142. Ions from plasma source 140 interacts with, in a confined manner, target 106 to sputter material from target sputtering surface 150 of target 106. In the example of FIG. 1, a radio frequency coil 148 (or RF coil 148) is employed to generate the plasma although other plasma generating technologies may also be employed.

Plasma source 140 may be generally cylindrical in shape, symmetrical with respect to an imaginary central axis 160. In one or more embodiments, target 106 is positioned inside the plasma cloud, with sputter target surface 150 of target 106 being tilted at an acute angle relative to central axis 160 for efficient sputtering. The tilting of the target sputtering surface 150 of target 106 relative to central axis 160 enables a substantial portion of target sputtering surface 150 to be directed away from plasma source 140. Thus, when ions, from the plasma generated by plasma source 140 impact target sputtering surface 150 of target 106 to sputter off material, much of the sputtered material is directed away from plasma source 140 due to the tilt angle of the target sputtering surface. Accordingly, the amount of sputtered materials that back-sputter plasma source 140 may be minimized. Substrate 108 is shown directed toward target sputtering surface 150 to maximize deposition from materials sputtered off target sputtering surface 150. In one or more embodiments, a sputter shield 188 may be positioned at the opening of plasma source 140 inside chamber 104 to minimize back sputtering of sputtered target material into plasma source 140.

FIG. 1 further shows two magnets 170 and 172, which may be magnet coils or ring-shaped magnets. Magnet 170 and magnet 172 may produce magnetic fields with strengths that are asymmetrical, thereby enabling magnetic field lines to be shaped or steered such that the sputtered target is covered by a desirable resultant magnetic field and/or that the target is exposed to magnetic field lines with desirable strengths in desirable directions. As an example, the “bulge” of the magnetic field lines may be positioned by the asymmetrical magnets to substantially envelope the target. In one or more embodiments, the field strength of one or more of magnets 170 and 172 may be adjustable in situ based on process recipe needs.

Sputter target 106 may be disk shaped in one or more embodiments. The disk shape may maximize the efficiency of sputtering material from sputtering surface 150 that is directed toward substrate 108 while minimizing unwanted sputtering from other surfaces of sputter target 106. For example, edge 180, having a smaller exposed area than the area of target sputtering surface 150, would sputter off less material, thereby resulting in less unwanted sputtered material deposition in chamber 104. In one or more embodiments, edge 180 and back surface 182 may be shielded with an appropriate shield (e.g. shield 186, which may be grounded or electrically floating) to minimize and/or eliminated unwanted sputtering from edge 180 and back surface 182.

Sputter target 106 may be a circular disk or may be a polygonal disk of a polygonal shape. Target sputtering surface 150 may be planar, although a concave, convex, or non-planner surface 150 may be possible in one or more embodiments. In one or more embodiments, target 106 may have a configuration that is not disk-shaped but may still have a target sputtering surface directed away from plasma source 140 toward a substrate that is positioned outside of the plasma path.

As discussed, a source gas may be introduced into plasma generating region 142 of plasma source 140 to facilitate plasma generation. Unlike the prior art, since embodiments of the invention inject the source gas directly into plasma generating region 142, there is higher pressure within plasma generating region 142 to support a higher density plasma without requiring an unduly high amount of RF energy. Exhaust gas may be pumped from chamber 104 via port 190 as shown.

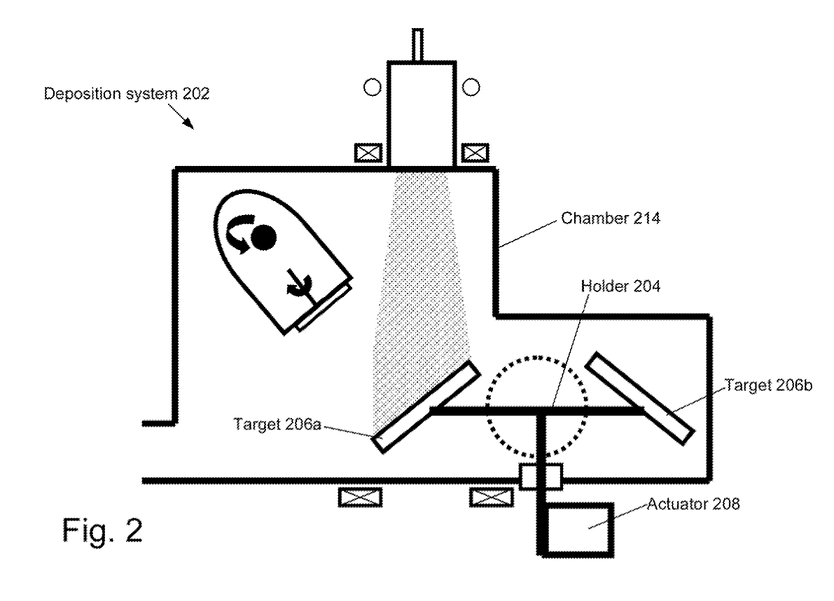

FIG. 2 shows a schematic representation illustrating a deposition system 202 in accordance with one or more embodiments of the invention. As illustrated in the example of FIG. 2, deposition system 202 may include a multi-target holder 204 configured for supporting a plurality of targets, such as a target 206a and a target 206b. Multi-target holder 204 may be configured to support more than two targets according to one or more embodiments. A target drive actuator 208 may be employed to selectively move one or more of targets 206a and 206b into position to be sputtered by the plasma inside chamber 214. The moving/positioning of different targets may be achieved in-situ, in one or more embodiments, to improve process efficiency (e.g., reducing/eliminating chamber stabilization time).

In this manner, different target shapes/sizes/materials may be available to facilitate different sputtering steps of the recipe. Actuator 208 may include a suitable actuating mechanism, such as an air-actuated mechanism, an electrically-actuated mechanism, a pneumatically-actuated mechanism, and/or a magnetically-actuated mechanism. In one or more embodiments, actuator 208 may include an electric stepper motor. The actuator assembly may involve gearing or chain or some type of suitable drive mechanism if desired.

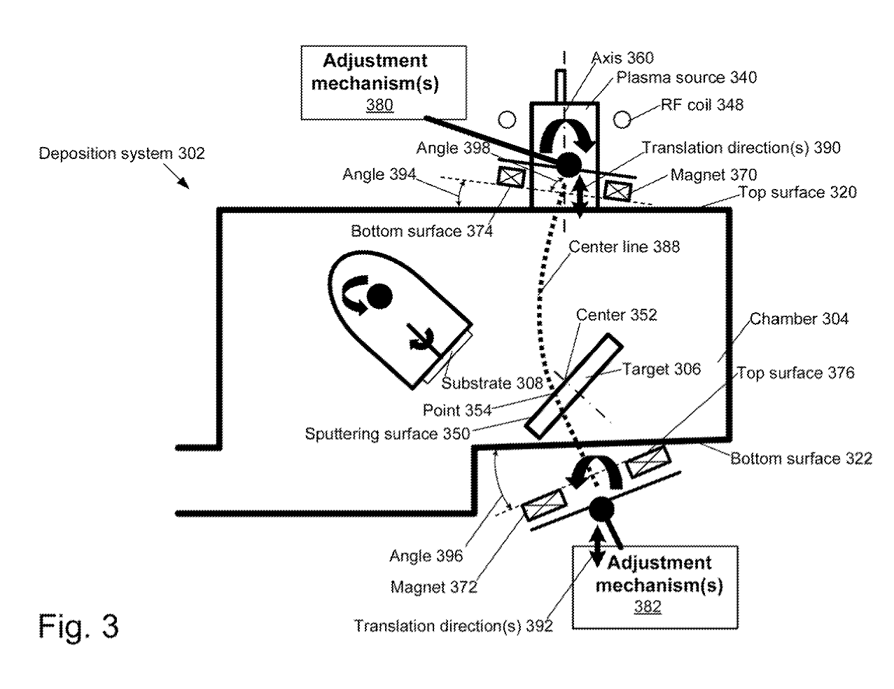

FIG. 3 shows a schematic representation illustrating a deposition system 302 in accordance with one or more embodiments of the invention. Deposition system 302 may include a plasma source 340, e.g., surrounded by a RF coil 348, for providing and sustaining plasma. Deposition system 302 may also include a chamber 304 for containing the plasma, at least a substrate to be processed (e.g., a substrate 308), and at least a target (e.g., a target 306) during the deposition process. Target 306 may include the material to be deposited on substrate 308 and/or one or more materials employed for producing the deposited material through interaction with the plasma. The plasma may physically and/or chemically interact with target 306 for sputtering the desirable material onto substrate 308. Similar to target 106 illustrated in the example of FIG. 1 discussed above, target 306 may be tilted for minimizing unwanted deposition on plasma source 340 and/or for improving deposition uniformity and efficiency. Substrate 308 may be properly oriented according to the orientation of the target for optimizing deposition efficiency and/or deposition uniformity on substrate 308.

Deposition system 302 may also include one or more magnets disposed outside of chamber 304 for steering the plasma to target 306 and/or for focusing the plasma on target 306. According to the tilted orientation (e.g., the size of the tilt angle) of target 306, the magnet(s) may be configured with one or more tilted orientations to compensate for the effects of the potentially lower plasma density at the lower portion of target 306 (which is relatively farther from plasma source 340 than the upper portion of target 306), thereby improving the uniformity of the utilization and consumption of target 306.

For example, deposition system 302 may include a top magnet 370 disposed above chamber 304 and/or a bottom magnet 372 disposed below chamber 304. Top magnet 370 (or a bottom surface 374 thereof) and/or bottom magnet 372 (or a top surface 376 thereof) may be oriented to be at an acute angle (e.g., angle 398) between 0 degree and 90 degrees with respect to an imaginary axis 360 of plasma source 340, wherein a circular cross section of a cylindrical portion of plasma source 340 may be symmetrical with respect to imaginary axis 360. The angle may be configured to be at least 75 degrees and less than 90 degrees to more effectively direct the plasma toward target 306. With the tilted orientation(s), top magnet 370 and/or bottom magnet 372 may produce at least a magnetic field with an imaginary center line 388 of the magnetic field passing through a sputtering surface 350 (i.e., a surface intended to interact with the plasma) of target 306 at a point 354 lower than a center 352 of sputtering surface 350. In other words, top magnet 370 and/or bottom magnet 372 may be oriented to make relatively more magnetic field lines pass through the lower portion of the tilted target 306, thereby increasing the plasma density at the lower part of sputtering surface 350 to compensate for the potential plasma density differences across sputtering surface 350 caused by the tilted orientation of target 306. As a result, plasma density may be substantially uniform over sputtering surface 350, and the consumption of target 306 may be substantially uniform across sputtering surface 350. Advantageously, target material of targets (such as target 306) may be optimally utilized, waste of target material potentially caused by uneven or concentrated consumption of targets may be minimized, costs associated with target material may be minimized, costs and time required for replacing targets may be minimized, and productivity for manufacturing devices may be improved.

In one or more embodiments, top magnet 370 (or bottom surface 374 thereof) and/or bottom magnet 372 (or top surface 376 thereof) may be oriented to be at an acute angle (e.g., angle 394 or angle 396) between 0 degree and 90 degrees with respect to a top surface 320 of chamber 304 and/or with respect to a bottom surface 322 of chamber 304. Angle 394 and/or angle 396 may be configured to be greater than 0 degree and at most 25 degrees to more effectively direct the plasma toward target 306.

Deposition system 302 may also include one or more adjustment mechanisms for adjusting the orientation(s) and/or the position(s) of top magnet 370 and/or bottom magnet 372. For example, deposition system 302 may include one or more mechanisms 380 for rotating top magnet 370 to adjust the size(s) of angle 398 and/or angle 394, for example, according to the planned orientation and/or the real orientation of target 306, for optimizing the utilization of target 306 and/or for optimizing material deposition on substrate 308. Mechanism(s) 380 and/or a different mechanism of deposition 302 may move/position top magnet 370 with respect to plasma source 340 in one or more translation directions 390 parallel to or aligned with imaginary axis 360 of plasma source 340 for further optimizing plasma distribution, thereby optimizing deposition uniformity and/or material utilization uniformity. Additionally or alternatively, deposition system 302 may include one or more mechanisms 382 and/or a different mechanism for rotating bottom magnet 372 to adjust the orientation of bottom magnet 372 (e.g., represented by angle 396) and/or for moving/positioning bottom magnet with respect to plasma source 340 in one or more translation directions 392 parallel to or aligned with imaginary axis 360, thereby optimizing the deposition uniformity and/or the material utilization uniformity.

Top magnet 370 and bottom magnet 372 may be ring-shaped, low-cost permanent magnets. In one or more embodiments, at least one of top magnet 370 and bottom magnet 372 may include an electromagnet for providing more controllability in optimizing the plasma distribution inside chamber 304.

As also illustrated in the example of FIG. 3, one or more embodiments of the invention may relate to a method for depositing material on a substrate (e.g., substrate 308) utilizing deposition system 302. The method may include disposing substrate 308 and target 306 inside chamber 304, wherein target 306 may be disposed with sputtering surface 350 facing substrate 308. The method may also include tilting target 306 such that target 306 is at an acute angle with respect to imaginary axis 360 and that a substantial portion of target 306 is disposed distantly from plasma source 340. The method may also include orient substrate 308 according to the tilted orientation of target 306. Advantageously, the unwanted deposition on plasma source 340 may be minimized, and the uniformity and the efficiency of the deposition on substrate 308 may be optimized.

The method may also include producing a magnetic field inside chamber 304 using one or more magnets, such as top magnet 370 (disposed above the chamber 304) and/or bottom magnet 372 (disposed below the chamber 304), for influencing the distribution of the plasma inside the chamber. The method may also include arranging target 306, top magnet 370, and/or top magnet 372 to make imaginary center line 388 of the magnetic field pass through sputtering surface 350 of target 306 at point 354 that is lower than center 352 of sputtering surface 350. In other words, the method may involve configuring orientation(s) and/or position(s) of top magnet 370, magnet 372, and/or target 306 to direct more magnetic field lines to pass through the lower portion of the tilted target 306 than the upper portion of the tilted target 306, which is closer to plasma source 340 than the lower portion of target 306. Through the arrangement, the method may compensate for the potential plasma density differences across sputtering surface 350 caused by the tilted orientation of target 306. Advantageously, the utilization of target 306 may be optimized, costs and time required for replacing targets may be minimized, and productivity for manufacturing devices may be improved.

In one or more embodiments, the method may include adjusting angle 398 to a size of at least 75 degrees and less than 90 degrees, and/or adjusting at least one of angle 394 and angle 396 to a size of greater than 0 degree and at most 25 degrees, for effectively direct the plasma toward target 306 with more magnetic field lines passing through the lower portion of target 306.

In one or more embodiments, the method may include adjusting the orientation(s) and/or position(s) of top magnet 370, magnet 372, and/or target 306 during the deposition process, for example, utilizing adjustment mechanism(s) 380, adjustment mechanism(s) 382, and/or an adjustment mechanism (such as target support 110 illustrated in the example of FIG. 1) coupled with target 306. Advantageously, the utilization of target 306 may be dynamically optimized.

As can be appreciated from the foregoing, embodiments of the invention may improve sputter deposition efficiency on the substrate. Embodiments of the invention may also minimize unwanted back-sputter toward the sputter source and unwanted sputter deposition on interior surfaces of a processing chamber. Embodiments of the invention may also improve process efficiency by injecting the source gas into the plasma generating region, thereby enabling the generation of high density plasma without requiring an undue amount of RF power. Embodiments of the invention may also enhance process control through the use of target orientation/position adjustment mechanisms and/or substrate orientation/position adjustment mechanisms. Embodiments of the invention may also enhance process control by shaping the magnetic field lines utilizing one or more magnets, thereby shaping the plasma to maximize target sputtering efficiency. Since the magnetic field lines may be adjustable in situ and/or the target/substrate can be tilted/rotated in situ, process control may be dynamically optimized, and productivity may be, improved.

Embodiments of the invention may also improve the uniformity of target material utilization and consumption. Advantageously, waste of target material potentially caused by uneven or concentrated consumption of targets may be minimized, costs associated with target material may be minimized, costs and time required for replacing targets may be minimized, and productivity for manufacturing devices may be improved.

Embodiments of the invention may also enable dynamic adjustment of plasma distribution. Advantageously, target material utilization may be dynamically optimized for further reducing waste and saving costs.

While this invention has been described in terms of several embodiments, there are alterations, permutations, and equivalents, which fall within the scope of this invention. It should also be noted that there are many alternative ways of implementing the methods and apparatuses of the present invention. For example, although the apparatus is discussed in details to facilitate understanding, the present invention also covers methods for processing substrates in a deposition system utilizing one or more of the discussed features. As another example, the present invention also covers methods for manufacturing deposition systems that employ one or more of the discussed features. Additionally, it is intended that the abstract section, having a limit to the number of words that can be provided, be furnished for convenience to the reader and not to be construed as limiting of the claims herein. It is therefore intended that the following appended claims be interpreted as including all such alterations, permutations, and equivalents as fall within the true spirit and scope of the present invention.

What is claimed is:

1. A system for depositing material on a substrate using plasma and a target, the target including at least one of the material and a second material, the system comprising:
a plasma source for providing the plasma;
a chamber for containing the substrate, the plasma, and the target during deposition of the material on the substrate; and
a first magnet disposed above the chamber or disposed below the chamber for influencing distribution of the plasma inside the chamber, at least one of a bottom surface of the first magnet and a top surface of the first magnet being at a first angle with respect to an imaginary axis of the plasma source, a circular cross section of the plasma source being symmetrical with respect to the imaginary axis of the plasma source, the first angle being greater than 0 degree and less than 90 degrees.

2. The system of claim 1 wherein an imaginary center line of a magnetic field produced inside the chamber by at least the first magnet passes through a point on a sputtering surface of the target when the target is present inside the chamber, the point being lower than a center of the sputtering surface of the target when the target is present inside the chamber, the sputtering surface of the target facing the substrate when the substrate and the target are present inside the chamber.

3. The system of claim 1 further comprising an adjustment mechanism for rotating the first magnet to adjust a size of the first angle.

4. The system of claim 3 wherein the adjustment mechanism is further configured for moving the first magnet in at least one direction parallel to or aligned with the imaginary axis of the plasma source.

5. The system of claim 1 further comprising an adjustment mechanism for moving the first magnet in at least one direction parallel to or aligned with the imaginary axis of the plasma source.

6. The system of claim 1 wherein the at least one of the bottom surface of the first magnet and the top surface of the first magnet is at a second angle with respect to at least one of a top surface of the chamber and a bottom surface of the chamber, the second angle being greater than 0 degree and being at most 25 degrees.

7. The system of claim 1 wherein the first magnet is disposed above the chamber.

8. The system of claim 1 wherein the first magnet is disposed below the chamber.

9. The system of claim 1 further comprising a second magnet disposed below the chamber, a top surface of the second magnet being at a second angle with respect to the imaginary axis of the plasma source, the second angle being greater than 0 degree and less than 90 degrees, the first magnet being disposed above the top surface of the chamber, the chamber being disposed between the first magnet and the second magnet.

10. The system of claim 9 wherein an imaginary center line of a magnetic field produced inside the chamber by the first magnet and the second magnet passes through a point on a sputtering surface of the target when the target is present inside the chamber, the point being lower than a center of the sputtering surface of the target when the target is present inside the chamber, the sputtering surface of the target facing the substrate when the substrate and the target are present inside the chamber.

10. The system of claim 9 further comprising:
a first adjustment mechanism for rotating the first magnet to adjust a size of the first angle; and
a second adjustment mechanism for rotating the second magnet to adjust a size of the second angle.

11. The system of claim 9 further comprising:
a first adjustment mechanism for moving the first magnet in at least one direction parallel to or aligned with the imaginary axis of the plasma source; and
a second adjustment mechanism for moving the second magnet in one or more directions parallel to or aligned with the imaginary axis of the plasma source.

12. The system of claim 9 wherein at least one of the first magnet and the second magnet includes an electromagnet.

13. A method for manufacturing a deposition system, the deposition system being for use in depositing material on a substrate using plasma and a target, the target including at least one of the material and a second material, the method comprising:
providing a first magnet;
providing a chamber for containing the substrate, the plasma, and the target during deposition of the material on the substrate;
coupling the chamber with a plasma source; and
configuring a first angle between the first magnet and an imaginary axis of the plasma source to be greater than 0 degree and less than 90 degrees, at least one of a bottom surface of the first magnet and a top surface of the first magnet being at the first angle with respect to the imaginary axis of the plasma source, a circular cross section the plasma source being symmetrical with respect to the imaginary axis of the plasma source.

14. The method of claim 13 further comprising:
providing a second magnet;
disposing the chamber between the first magnet and the second magnet; and
configuring a second angle between the second magnet and the imaginary axis of the plasma source to be greater than 0 degree and less than 90 degrees, at least one of a bottom surface of the second magnet and a top surface of the second magnet being at the second angle with respect to the imaginary axis of the plasma source.

15. A method for depositing material on a substrate using plasma and a target, the target including at least one of the material and a second material, the method comprising:
disposing the substrate and the target inside a chamber, the chamber being configured for containing the plasma;
producing a magnetic field inside the chamber using at least a first magnet for influencing distribution of the plasma inside the chamber; and
arranging at least one of the target and the first magnet to make an imaginary center line of the magnetic field pass through a point on a sputtering surface of the target, the point being lower than a center of the sputtering surface of the target, the sputtering surface of the target facing the substrate.

16. The method of claim 15 further comprising configuring a first angle between the first magnet and an imaginary axis of a plasma source according to an orientation of the target, at least one of a bottom surface of the first magnet and a top surface of the first magnet being at the first angle with respect to the imaginary axis of the plasma source, a circular cross section the plasma source being symmetrical with respect to the imaginary axis of the plasma source, the plasma source being configured for providing the plasma.

17. The method of claim 16 further comprising configuring the first angle to be greater than 0 degree and less than 90 degrees.

18. The method of claim 15 further comprising:
using at least a second magnet for producing the magnetic field inside the chamber; and
arranging at least one of the first magnet and the second magnet for the imaginary center line of the magnetic field to pass through the point on the sputtering surface of the target.

19. The method of claim 18 further comprising configuring a second angle between the second magnet and the imaginary axis of the plasma source to be greater than 0 degree and less than 90 degrees, at least one of a bottom surface of the second magnet and a top surface of the second magnet being at the second angle with respect to the imaginary axis of the plasma source.

20. The method of claim 15 further comprising adjusting a size of an angle between the first magnet and an imaginary axis of a plasma source when processing the substrate, at least one of a bottom surface of the first magnet and a top surface of the first magnet being at the angle with respect to the imaginary axis of the plasma source, a circular cross section the plasma source being symmetrical with respect to the imaginary axis of the plasma source, the plasma source being configured for providing the plasma.
